(19) United States
(12) Patent Application Publication
(10) Pub. No.: US 2026/0113937 A1
(43) Pub. Date: Apr. 23, 2026

(54) MEMORY DEVICE AND METHOD FOR MANUFACTURING MEMORY DEVICE

(71) Applicants: HYUNDAI MOTOR COMPANY, Seoul (KR); Kia Corporation, Seoul (KR); Research & Business Foundation SUNGKYUNKWAN UNIVERSITY, Suwon-si (KR)

(72) Inventors: Jong Seok LEE, Hwaseong-si (KR); Ui Yeon WON, Hwaseong-si (KR); Ho Sung CHOI, Suwon-si (KR); Woo Jong YU, Suwon-si (KR); Hong Woon YUN, Suwon-si (KR)

(21) Appl. No.: 19/229,482

(22) Filed: Jun. 5, 2025

(30) Foreign Application Priority Data
Oct. 21, 2024 (KR) 10-2024-0143683

(51) Int. Cl. H10B 41/30; G11C 16/14

(52) U.S. Cl. CPC H10B 41/30; G11C 16/14

(57) ABSTRACT

A two-electrode memory device includes a substrate, a floating gate disposed on the substrate and configured to store electrons, a tunneling insulating film disposed on the floating gate and configured provide electron tunneling, a channel disposed on the tunneling insulating film, a source electrode and a drain electrode that are each disposed on the tunneling insulating film and have electrical connection with the channel, and a plurality of metal nanodots disposed in the tunneling insulating film.

### CROSS-REFERENCE TO RELATED APPLICATION

This application claims priority to and the benefit of Korean Patent Application No. 10-2024-0143683, filed in the Korean Intellectual Property Office, on Oct. 21, 2024, the entire contents of which are incorporated herein by reference.

### TECHNICAL FIELD

The present disclosure relates to a memory device and a method for manufacturing a memory device.

### BACKGROUND

A demand for a high-speed, low-power, and large-capacity storage device is rapidly increasing with the development of a modern electronic device. For example, a nonvolatile memory may retain data even when power is cut off. A representative nonvolatile memory may be a flash memory. The flash memory has been widely used in various electronic devices. The flash memory can adopt a floating gate structure for storing the data to thus inject or remove electrons into or from a floating gate, thereby storing or deleting the data. In general, logic 0 can refer to a state where the electrons are stored in the floating gate, and logic 1 may refer to a state where no electron exists in the floating gate. Through this structure, the flash memory can perform a function of the nonvolatile memory.

The flash memory may have some limitations despite its commerciality. First, there may be a power consumption problem. A large voltage may be consumed to store or erase the data in or from the floating gate, which may result in high power consumption and a slow operational speed. To compensate for this shortcoming, a method such as page-based writing and block-based erasing may be used. Second, there may be difficulty in expressing multi-states. In order to express the multi-states based on the floating gate, a charge difference between the respective states may be cleared. In some cases, overlap between the states may occur during a read operation, thus making it difficult to accurately read the data. A software complementary device such as incremental step pulse programming (ISPP) or a flash translation layer (FTL) may be used. Third, there is a limit to the miniaturization of the device. The flash memory may have four electrodes, including a gate electrode, a source electrode, a drain electrode, and a semiconductor substrate, and accordingly, there is a limit to reducing its size due to the presence of the gate electrode and a gate insulator. These limitations may hinder the integration of memory cells and make the development of a high-density memory device difficult.

### SUMMARY

The present disclosure describes a memory device that can perform reading, writing, and erasing operations using a drain electrode and a source electrode without a control gate or a gate insulator, and a method for manufacturing a memory device.

The present disclosure describes a memory device including a plurality of metal nanodots that are disposed on a floating gate to thus improve an operational speed and reduce an operational voltage, and a method for manufacturing a memory device.

According to one aspect of the subject matter described in this application, a two-electrode memory device includes a substrate, a floating gate disposed on the substrate and configured to store electrons, a tunneling insulating film disposed on the floating gate, a channel disposed on the tunneling insulating film, a source electrode and a drain electrode that are each disposed on the tunneling insulating film and that have electrical connection with the channel, and a plurality of metal nanodots disposed in the tunneling insulating film and configured to provide electron tunneling between the floating gate and the channel through the tunneling insulating film.

Implementations according to this aspect can include one or more of the following features. For example, the floating gate can include a metal material and at least one of graphene, polysilicon, or silicon nitride (SiN). In some examples, the plurality of metal nanodots are made from a metal thin film that is deposited on the floating gate through an atomic layer deposition (ALD) process and annealed while depositing the tunneling insulating film on the metal thin film. In some implementations, the plurality of metal nanodots can include at least one of gold (Au), aluminum (Al), copper (Cu), silver (Ag), nickel (Ni), or germanium (Ge).

In some implementations, the two-electrode memory device can be configured to perform a write operation or an erase operation based on (i) connecting one electrode of the source electrode or the drain electrode to a ground and (ii) applying a voltage to the other electrode of the source electrode or the drain electrode. In some examples, the floating gate can be configured to store the electrons based on a negative voltage being applied to the other electrode, and to discharge the electrons based on a positive voltage being applied to the other electrode.

In some implementations, the substrate can include at least one of polyimide or polydimethylsiloxane. In some implementations, the tunneling insulating film can include at least one of aluminum oxide (Al₂O₃), hexagonal boron nitride, silicon nitride (Si₃N₄), silicon oxide (SiO₂), or hafnium oxide (HfO₂). In some implementations, the channel can include at least one of zinc oxide (ZnO), molybdenum disulfide (MoS₂), molybdenum diselenide (MoSe₂), tungsten disulfide (WS₂), tungsten diselenide (WSe₂), silicon (Si), germanium (Ge), a semiconducting carbon nanotube, or black phosphorus. In some implementations, each of the source electrode and the drain electrode can include a stacked structure of chromium (Cr) and gold (Au).

In some implementations, the channel can include a negative n-type semiconductor, where the channel is configured to decrease a resistance of the channel based on the floating gate having a positive potential, and increase the resistance of the channel based on the floating gate having a negative potential.

In some implementations, the channel can include a positive p-type semiconductor, where the channel is configured to increase a resistance of the channel based on the floating gate having a positive potential, and to decrease the resistance of the channel based on the floating gate having a negative potential.

According to another aspect, a method for manufacturing a two-electrode memory device includes providing a substrate, forming a floating gate on the substrate, the floating gate being configured to store electrons, depositing a metal thin film on the floating gate, depositing a seed layer on the metal thin film, depositing a tunneling insulating film on the seed layer and performing an annealing process while depositing the tunneling insulating film to thereby form a plurality of metal nanodots with the metal thin film in the tunneling insulating film, forming a channel on the tunneling insulating film, and forming a source electrode and a drain electrode on the tunneling insulating film, where the source electrode and the drain electrode each have electrical connection with the channel, and the plurality of metal nanodots are configured to provide electron tunneling between the floating gate and the channel through the tunneling insulating film.

Implementations according to this aspect can include one or more of the following features. For example, the floating gate can include a metal material and at least one of graphene, polysilicon, or silicon nitride (SiN). In some examples, the plurality of metal nanodots include at least one of gold (Au), aluminum (Al), copper (Cu), silver (Ag), nickel (Ni), or germanium (Ge). In some examples, the substrate can include at least one of polyimide or polydimethylsiloxane. In some examples, the tunneling insulating film can include at least one of aluminum oxide (Al₂O₃), hexagonal boron nitride, silicon nitride (Si₃N₄), silicon oxide (SiO₂), or hafnium oxide (HfO₂). In some examples, the channel can include at least one of zinc oxide (ZnO), molybdenum disulfide (MoS₂), molybdenum diselenide (MoSe₂), tungsten disulfide (WS₂), tungsten diselenide (WSe₂), silicon (Si), germanium (Ge), a semiconducting carbon nanotube, or black phosphorus. In some examples, each of the source electrode and the drain electrode can include a stacked structure of chromium (Cr) and gold (Au). In some examples, the seed layer can include an aluminum layer.

### BRIEF DESCRIPTION OF THE DRAWINGS

FIG. 1 is a view for describing an example of a memory device.

FIGS. 2 through 12 are views for describing an example method for manufacturing a memory device.

FIG. 13 is a view for describing an implementation of the memory device.

FIGS. 14A to 16F are views showing example performance features of the memory device, where FIGS. 14A, 14B, and 15A show features of the memory device in related art, and FIGS. 14C, 14D, 15B, and 16A to 16F show features of the memory device according to the present disclosure.

### DETAILED DESCRIPTION

Hereinafter, implementations of the present disclosure are described in detail with reference to the accompanying drawings so that those skilled in the art to which the present disclosure pertains can easily practice the present disclosure. However, the present disclosure can be implemented in various different forms and is not constrained to the implementations provided herein. In addition, in the drawings, portions unrelated to the description are omitted to clearly describe the present disclosure, and similar portions are denoted by similar reference numerals throughout the specification.

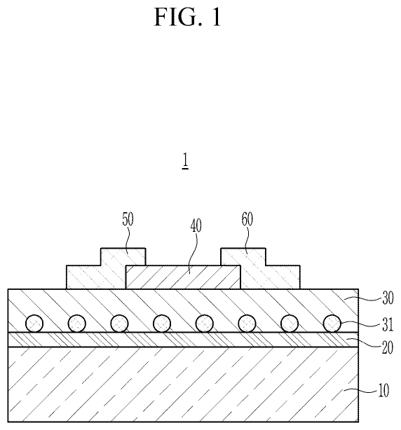

FIG. 1 is a view for describing an example of a memory device.

In some implementations, referring to FIG. 1, a memory device 1 may include a substrate 10, a floating gate 20, a tunneling insulating film (or tunneling insulator) 30, a channel 40, a source electrode 50, and a drain electrode 60. The memory device 1 can be a non-transitory memory device that includes or is part of an electric circuit.

The memory device 1 can be implemented as a two-electrode floating gate memory device. The two-electrode floating gate memory device can be a memory device capable of storing data by using only two electrodes, while some memory devices include a three-electrode or four-electrode structure. For this purpose, the two-electrode floating gate memory device can be implemented to perform its operation by using only the source electrode and the drain electrode, without using the gate electrode used in the three-electrode or four-electrode structure.

The substrate 10 can be a silicon substrate doped with impurities or a silicon on insulator (SOI) substrate. The SOI substrate can include a substrate layer corresponding to a typical silicon wafer, an insulating layer made of silicon oxide (SiO₂) or another insulating material to provide electrical insulation, and a silicon layer formed on the insulating layer to provide an active region of the device. The substrate can include an epitaxial layer. The epitaxial layer can be a thin semiconductor layer deposited to have the same crystal structure as the substrate, and can improve an electrical feature of the device through high-quality crystal growth.

In some implementations, the substrate 10 can include a material having elasticity. For example, the substrate 10 can include a polymeric material having elasticity, for example, at least one of polyimide or polydimethylsiloxane. The substrate 10 can include such a material to thus be used in a flexible electronic device or the like. In particular, polydimethylsiloxane can have biocompatibility and can be used in the electronic device for a purpose related to a medical or life science field.

The floating gate 20 can be formed on the substrate 10 and store the data. In detail, the floating gate 20 can include an insulated conductor capable of storing electrons. A state of a memory cell, i.e., logic 0 or logic 1, can be determined by injecting or removing the electrons into or from the floating gate 20. In detail, the electrons can be injected into the floating gate 20 from the source electrode 50 or the drain electrode 60 when a voltage for a write operation is applied to the electrode. When the electrons are stored in the floating gate 20, the floating gate 20 can become negatively charged, thereby changing a threshold voltage of a transistor. This state can be interpreted as logic 0. In some examples, the electrons stored in the floating gate 20 can be removed therefrom when a voltage for an erase operation is applied to the electrode, that is, when the voltage for the write operation is applied to the electrode in an opposite direction. This state where the electrons are removed from the floating gate 20 can be interpreted as logic 1. The floating gate 20 can maintain a charge stored therein even when power is cut off, thus storing the data for a long time period as a nonvolatile memory.

In some implementations, the floating gate 20 can include both a metal and a material capable of trapping the electrons. For example, the floating gate 20 can include the metal and at least one of graphene, polysilicon, or silicon nitride (SiN).

In some cases of a flash memory device, the charge can be injected into or removed from the floating gate through the gate electrode and the substrate. In some implementations, the charge can be injected into or removed from the floating gate 20 through the drain electrode 60. The charge can be injected into or removed from the floating gate 20 when a voltage of the threshold voltage (e.g., 3 V) or more, at which the electrons and holes can tunnel through the tunneling insulating film 30, is applied to the drain electrode 60.

The tunneling insulating film 30 can be formed on the floating gate 20 and provide electron tunneling. The tunneling insulating film 30 can include a thin insulating layer allowing the electrons to be moved through quantum tunneling. That is, the tunneling insulating film 30 can function to adjust the charge tunneling and store the charge tunneled to the floating gate 20. A thickness of the tunneling insulating film 30 can be adjusted appropriately. If the tunneling insulating film 30 is thin, a charge storage capacity of the floating gate can be reduced, although the charge tunneling is generated even at a low voltage. In some examples, if the tunneling insulating film 30 is thick, a voltage for the charge tunneling can be increased to thus increase the operational voltage and power consumption of the memory although the charge is stored in the floating gate for a long time period. In some implementations, the thickness of the tunneling insulating film 30 can range from 3 nm to 11 nm. In some implementations, the thickness of the tunneling insulating film 30 can be 7 nm.

In some implementations, the tunneling insulating film 30 can include at least one of aluminum oxide (Al₂O₃), hexagonal boron nitride, silicon nitride (Si₃N₄), silicon oxide (SiO₂), or hafnium oxide (HfO₂).

In some implementations, the tunneling insulating film 30 can include a plurality of metal nanodots 31. In some cases, a two-electrode floating gate memory can operate with a high operational voltage of 6 V for the electrons and holes to tunnel and reach the floating gate. In some implementations, a memory device can be configured to perform the write operation and the erase operation even at the low voltage of 3 V level by forming the plurality of metal nanodots 31 between the tunneling insulating film 30 and the floating gate 20.

When one electrode (for example, the source electrode 50) is grounded for the write operation and the erase operation and the voltage is applied to an opposite electrode (for example, the drain electrode 60), an electric field can be concentrated on several nanodots disposed below the electrode (for example, the drain electrode 60). This concentration can reduce the voltage for the electrons and holes to tunnel into the floating gate 20. It can be possible to reduce the operational voltage of the floating gate memory, and a metal nanodot-based floating gate memory device can have superior performance in various memory features such as data retention, reliability, and speed compared to other memory devices.

In order to form such metal nanodots, a single layer of graphene can be transferred onto a semiconductor substrate, and a metal thin film can then be deposited on the graphene to have a thickness of, for example, 2 nm. While depositing the insulating film through a subsequent atomic layer deposition (ALD) process (for example, performed at 250° C. and for 45 minutes), the metal thin film can be annealed and agglomerated into spherical shapes, thus forming the plurality of metal nanodots. The thickness of the metal thin film deposited to form the metal nanodot can preferably be adjusted appropriately. For example, it can be seen that a dot shape is formed when the metal thin film is deposited to have a smaller thickness of 3 nm or less and the annealing is then performed thereon. In some cases, a mesh shape can be formed rather than the dot shape when the metal thin film is deposited to have a greater thickness, for example, exceeding 3 nm. Therefore, the thickness of the deposited metal thin film can preferably be 5 nm or less. In some implementations, the thickness of the deposited metal thin film can be 2 nm.

In some implementations, the plurality of metal nanodots can be formed using the Ostwald Ripening method.

For example, the plurality of metal nanodots 31 can be formed by depositing the metal thin film on the floating gate 20 through the ALD process and performing the annealing thereon. In some implementations, the plurality of metal nanodots 31 can include at least one of gold (Au), aluminum (Al), copper (Cu), silver (Ag), nickel (Ni), or germanium (Ge).

The channel 40 can be formed on the tunneling insulating film 30. The channel 40 can provide a passage for the charge to be moved between the source electrode 50 and the drain electrode 60.

In some implementations, the channel 40 can include at least one of zinc oxide (ZnO), molybdenum disulfide (MoS₂), molybdenum diselenide (MoSe₂), tungsten disulfide (WS₂), tungsten diselenide (WSe₂), silicon (Si), germanium (Ge), a semiconducting carbon nanotube, or black phosphorus.

In some implementations, the channel 40 can include a negative n-type semiconductor, and a resistance of the channel 40 can be reduced when a potential of the floating gate 20 indicates a positive potential. In some examples, the resistance of the channel 40 can be increased when the potential of the floating gate 20 indicates a negative potential. In some other implementations, the channel 40 can include a positive p-type semiconductor, and the resistance of the channel 40 can be increased when the potential of the floating gate 20 indicates the positive potential. In some examples, the resistance of the channel 40 can be reduced when the potential of the floating gate 20 indicates the negative potential.

The source electrode 50 and the drain electrode 60 can each be formed on the tunneling insulating film 30 and have an electrical connection with the channel 40, respectively. That is, the source electrode 50 and the drain electrode 60 can be disposed at both ends of the channel 40, and can each have the electrical connection with the channel 40.

In some implementations, the source electrode 50 and the drain electrode 60 can have a stacked structure of chromium (Cr) and gold (Au).

As described above, the write operation or the erase operation of the memory device 1 can be performed by grounding one of the source electrode 50 and the drain electrode 60 (for example, the source electrode 50) and applying the voltage to the other electrode (for example, the drain electrode 60). Here, the electrons can be stored in the floating gate 20 and the floating gate 20 can have a negative charge when the negative voltage is applied to the other electrode (for example, the drain electrode 60), and the electrons can be removed from the floating gate 20 when the positive voltage is applied to the other electrode (for example, the drain electrode 60).

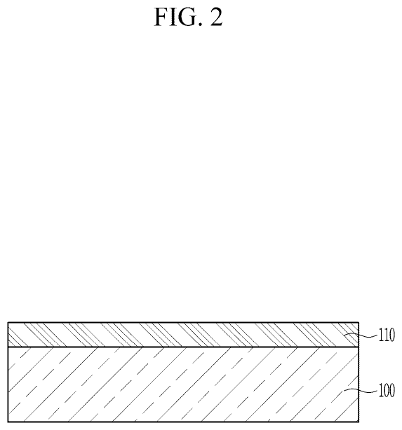

FIGS. 2 through 12 are views for describing an example method for manufacturing a memory device.

Referring to FIG. 2, the method for manufacturing a memory device may be a method for manufacturing a two-electrode floating gate memory device, which can include providing substrates 100 and 110. In some implementations, the substrates 100 and 110 can include, for example, an n-type silicon layer 100 and a silicon oxide (SiO₂) layer 110.

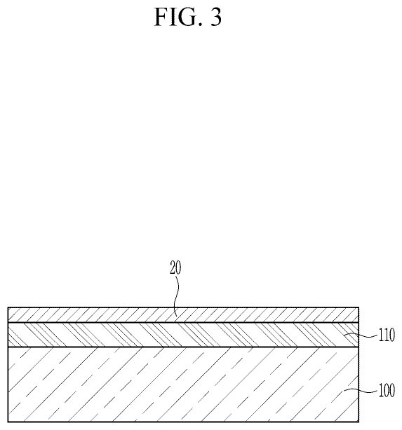

Referring to FIG. 3, the method can include forming a floating gate 20 capable of storing electrons on the substrates 100 and 110. In some implementations, the floating gate 20 can be formed by transferring graphene onto the substrate. For example, the graphene can be grown on a substrate made of a metal such as copper (Cu) or nickel (Ni), for example, through a chemical vapor deposition (CVD) process. A polymer layer can be coated on the grown graphene to protect and support the graphene from damage. The graphene coated with the polymer can be separated from the metal substrate through an etching process. The separated graphene can be transferred onto the substrates 100 and 110 after a washing process, and the polymer layer can then be removed from the graphene.

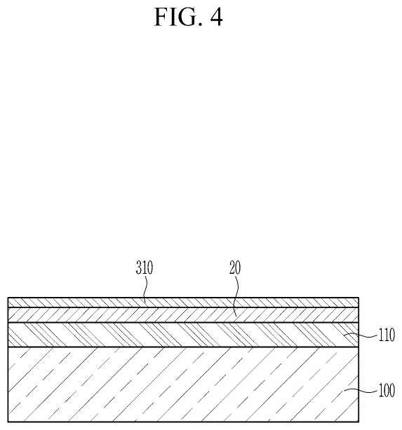

Referring to FIG. 4, the method can include depositing a metal thin film 310 on the floating gate 20. In some implementations, the metal thin film 310 can include gold (Au), and have a thickness of, for example, 1 nm to 5 nm.

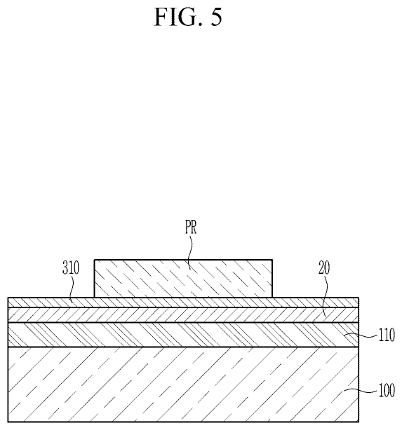

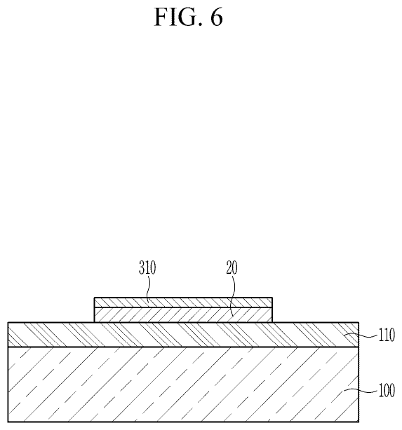

Referring to FIG. 5, the method can include forming a photoresist mask PR on the metal thin film 310 through a photoresist process. Next, referring to FIG. 6, the method can include etching the metal thin film 310 and the floating gate 20 based on a region defined by the photoresist mask PR.

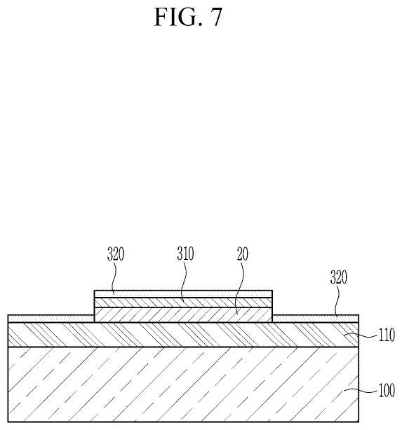

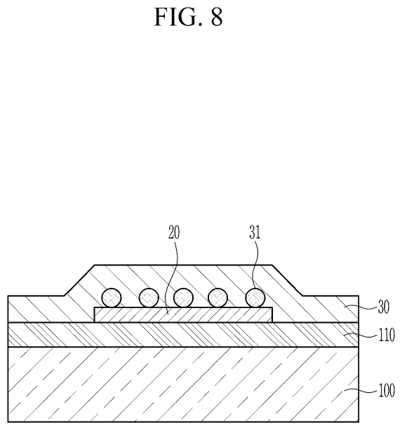

Referring to FIGS. 7 and 8, the method can include depositing a seed layer 320 on the metal thin film and depositing a tunneling insulating film 30 that provides electron tunneling. Here, the tunneling insulating film 30 can include a plurality of metal nanodots 31 generated through an annealing process performed while depositing the tunneling insulating film 30. That is, the metal thin film 310 can form the plurality of metal nanodots 31 during the annealing process. In some implementations, the seed layer can include an aluminum seed layer, and the seed layer 320 can be deposited to have a thickness of, for example, 2 nm. In some examples, the tunneling insulating film 30 can include aluminum oxide (Al₂O₃), and be deposited to have a thickness of, for example, up to 7 nm.

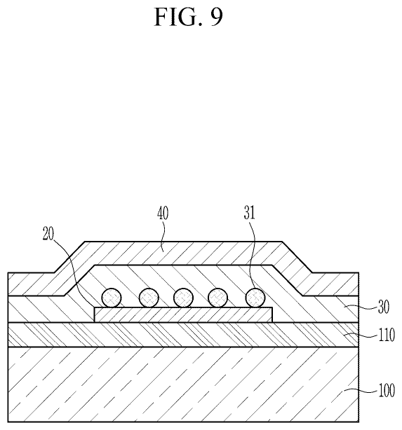

Referring to FIG. 9, the method can include forming a channel 40 on the tunneling insulating film 30. In some implementations, the channel 40 can include zinc oxide (ZnO), and can be deposited to have a thickness of up to 16 nm.

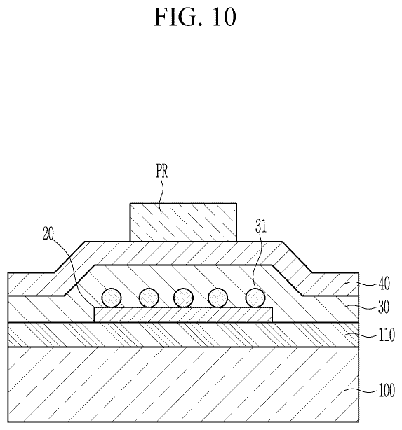

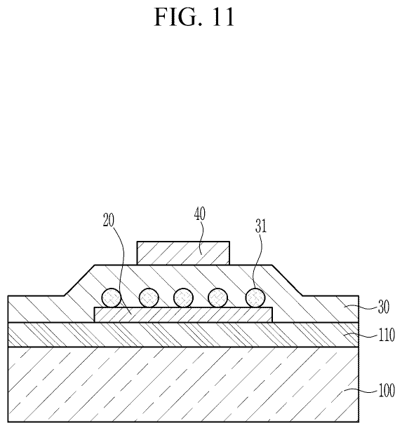

Referring to FIG. 10, the method can include forming the photoresist mask PR on the channel 40 through the photoresist process. Next, referring to FIG. 11, the method can include etching the channel 40 based on the region defined by the photoresist mask PR.

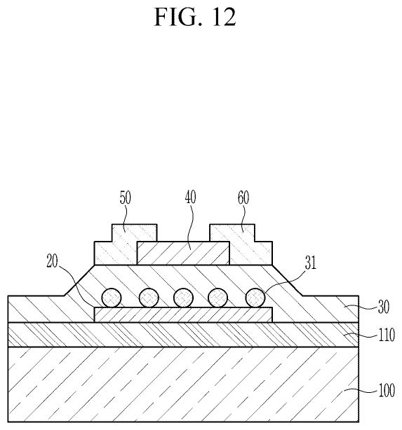

Referring to FIG. 12, the method can include forming a source electrode 50 and a drain electrode 60 each having an electrical connection with the channel 40 on the tunneling insulating film 30. In some implementations, the source electrode 50 and the drain electrode 60 can be formed to have a stacked structure of chromium (Cr) and gold (Au). For example, a thickness of the chromium (Cr) can be 5 nm and a thickness of the gold (Au) can be 50 nm.

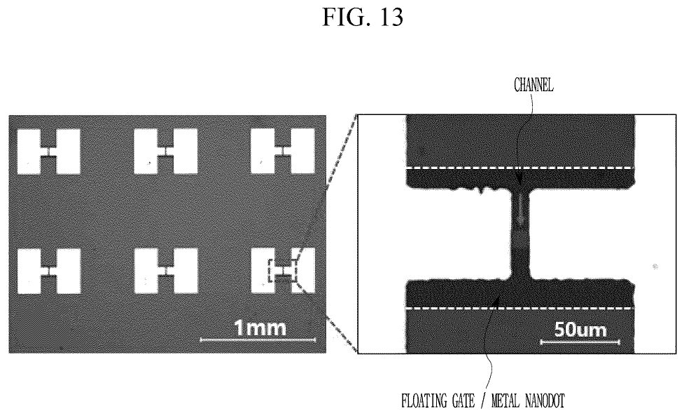

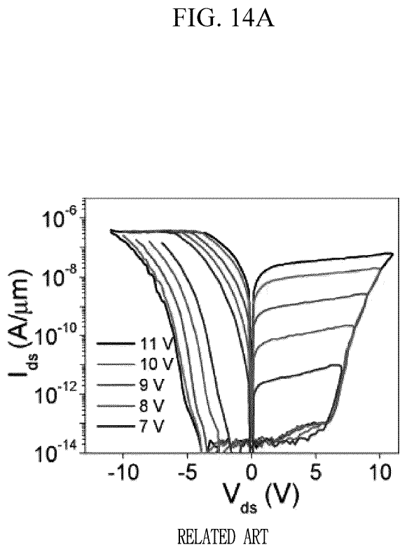

FIG. 13 is a view for describing an implementation of the memory device.

For example, FIG. 13 shows an image of the memory device captured using an optical microscope.

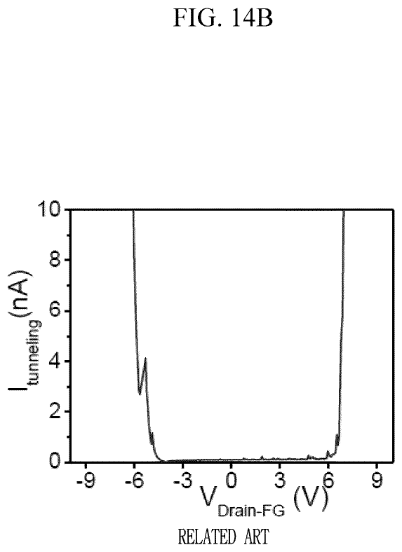

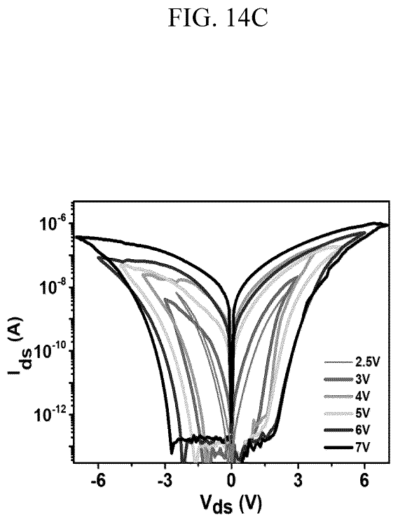

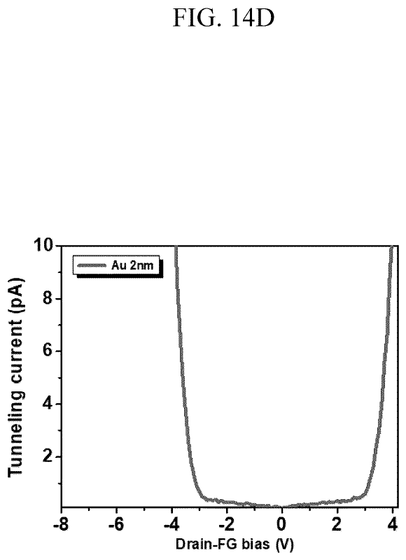

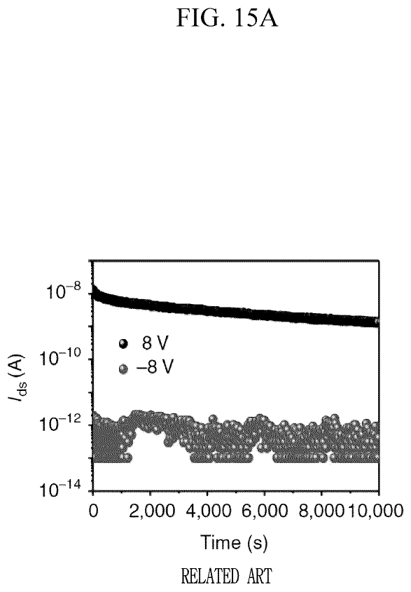

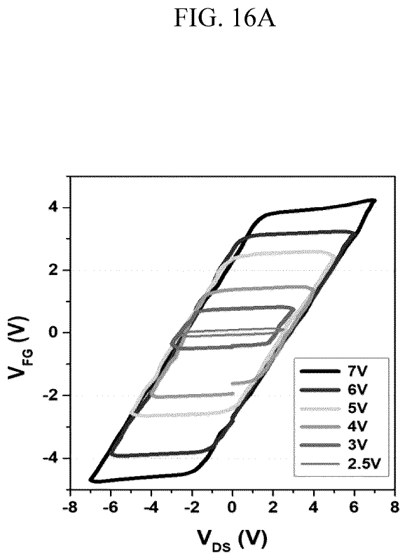

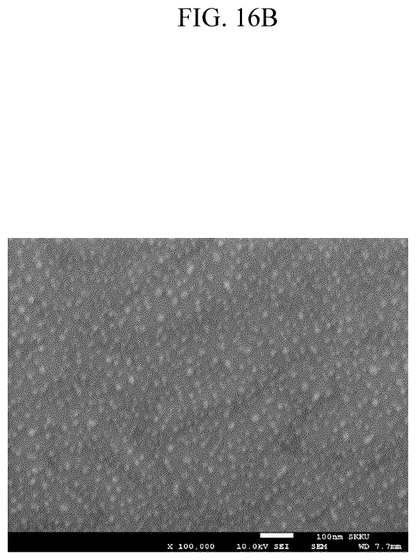

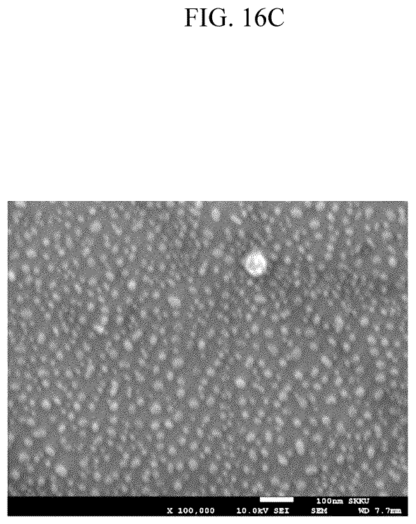

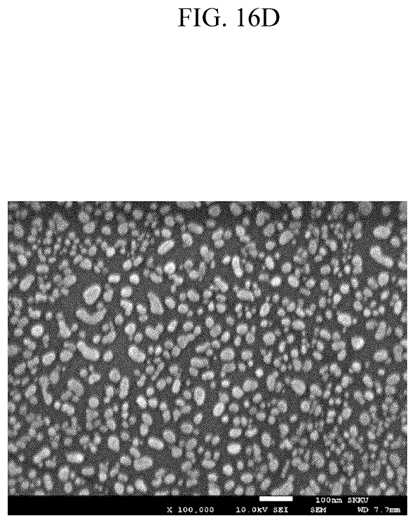

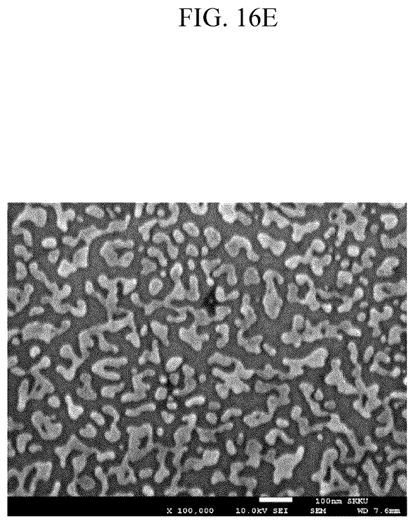

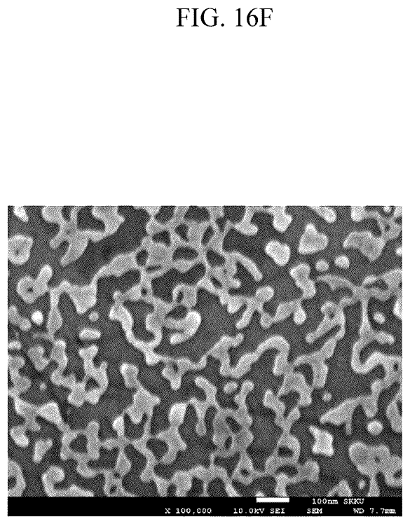

When the voltage is applied to the drain electrode, the tunneling phenomenon of the electrons and the holes can be generated, and the electrons and the holes can thus tunnel into the tunneling insulating film and then be stored in the floating gate. The electric field can be concentrated on the metal nanodots below the drain electrode, and the voltage for the tunneling can thus be reduced by, for example, 3 V or more (see FIGS. 14B and 14D) compared to other memory devices in related art. When the positive voltage is applied to the electrode, the holes can be stored in the floating gate, and the floating gate can thus have the positive potential. In some examples, when the negative voltage is applied to the electrode, the electrons can be stored in the floating gate, and the floating gate can thus have the negative charge (see FIG. 16A).

If the channel is the n-type semiconductor and the potential of the floating gate is the positive potential, a majority carrier of the channel, that is, the electrons, can be increased, which can reduce the resistance of the channel. In some examples, if the floating gate has the negative potential, the majority carriers, that is, the electrons, can be reduced, which can increase the resistance of the channel. If the channel is the p-type semiconductor, an opposite operation can be performed.

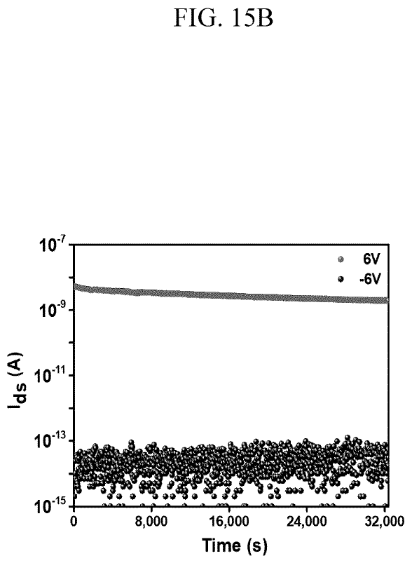

FIGS. 14A to 16F are views for describing example features of the memory device, where FIGS. 14A, 14B, and 15A show example features of the memory devices in related art, and FIGS. 14C, 14D, 15B, and 16A to 16F show example features of the memory device of the present disclosure.

FIG. 14A is a graph showing a drain-source current I_{ds} measured while applying drain-source voltages V_{ds} from +7 V to −7 V, +8 V to −8 V, . . . , and +11 V to −11 V, respectively. It can be seen that the memory feature of the device is expressed when sweeping at the voltage of 7 V or more. FIG. 14B is a graph showing a tunneling current I_{tunneling} based on a drain-floating gate voltage VDrain-FG. It can be seen that a tunneling current flows when the drain-floating gate voltage V_{Drain-FG} is 6 V or more. Here, the tunneling current I_{tunneling} can indicate a current flowing through the insulating film disposed between the electrode and the graphene. That is, when no metal nanodot is applied to a floating gate structure, a voltage of 6 V or more can be for the charge to pass through the tunneling insulating film having the thickness of 7 nm.

FIG. 14C is a graph showing the drain-source current I_{ds} measured while applying the drain-source voltage V_{ds} from +2.5 V to −2.5 V, +3 V to −3 V, . . . and +7 V to −7 V, respectively. It can be seen that the memory feature of the device is expressed when sweeping at the voltage of 2.5 V or more. FIG. 14D is a graph showing the tunneling current I_{tunneling} based on the drain-floating gate voltage V_{Drain-FG}. It can be seen that the tunneling current flows even when the drain-floating gate voltage V_{Drain-FG} is 3 V or more. That is, when the metal nanodot is applied to the floating gate structure, the charge can pass through the tunneling insulating film having the thickness of 7 nm at the voltage of 3 V.

Referring to FIGS. 15A and 15B, FIG. 15A is a graph acquired by measuring a retention time when no metal nanodot is applied to the floating gate structure, and shows the extent to which the charge stored in the gate remains unchanged over time, that is, the duration for which the current value remains constant. From a measurement result, it can be seen that the current (i.e., drain-source current I_{ds}) is reduced by about 10 times compared to an initial value over a period of about 10⁴ seconds(s). FIG. 15B is a graph acquired by measuring the retention time when the metal nanodot is applied to the floating gate structure, and from its measurement result, it can be seen that an almost constant current flows up to about 3.2×10⁴ s. From this result, it can be seen that when the metal nanodot is applied to the floating gate structure, the electrons may not be easily released from the floating gate, and the data can thus be retained for a long time period, thereby improving a long-term information storage capability of the memory device.

FIG. 16A is a graph showing a floating gate voltage V_{FG} measured while sweeping the drain-source voltage V_{ds} from +2.5 V to −2.5 V, +3 V to −3 V, . . . , and +7 V to −7 V, respectively, in the structure to which the metal nanodot is applied. It can be seen that no tunneling current is generated up to the drain-source voltage V_{ds} of 2.5 V, and no charge is thus accumulated in the floating gate, thereby leading to a voltage close to 0; whereas, when the drain-source voltage V_{ds} of 3 V or more is applied to the structure, the tunneling current is generated, and the charges are thus accumulated in the floating gate, thereby maintaining the floating gate voltage.

FIGS. 16A, 16C, 16D, 16E, and 16F show that the metal thin films having thicknesses of 1 nm, 2 nm, 3 nm, 4 nm, and 5 nm are respectively deposited on the graphene, the nanodots are formed through the annealing, and the results are then captured using a scanning electron microscope (SEM). It can be seen that the nanodots are formed to some extent when the thickness of the metal thin film is about 1 nm to 3 nm, and the mesh shape is formed when the thickness of the metal thin film is 4 nm or more. In some implementations, the thickness of the deposited metal thin film can preferably be about 2 nm.

The metal nanodot-based floating gate memory can provide the shorter write time and secure the increased efficiency of the electron movement compared to other floating gate memory devices in related art to thus improve the reliability of the entire memory device. The nanodot structure can concentrate the electric field within the floating gate to thus facilitate the electron movement, thereby lowering the operational voltage of the memory device and reducing its power consumption.

In some implementations, the two-electrode structure without the control gate or the control insulating film can be adopted, thus significantly improving the integration of the memory device compared to other memory devices in related art. That is, the additional structures such as the control gate can be removed to thus reduce the device size, thereby enabling the increased integration of the memory cells. In addition, the large number of the metal nanodots can be formed on the floating gate to thus concentrate the electric field thereon, thereby improving the operational speed and reducing the operational voltage. The metal nanodot can have the large work function to thus improve the data retention capability of the memory device. In particular, the metal such as gold (Au) can have the large work function, and the floating gate including the metal nanodots can thus ensure the capability to stably store the data for the long period of time. Accordingly, the information storage period can be extended. In addition, the metal nanodot-based floating gate structure can provide the shorter write time compared to the floating gate memory devices in related art to thus improve the reliability of the memory device. The concentrated electric field can enable the fast write and erase operations and the low-voltage operation, which can also reduce the power consumption.

Although the implementations of the present disclosure have been described in detail hereinabove, the scope of the present disclosure is not limited thereto. That is, various modifications and alterations made by those skilled in the art to which the present disclosure pertains by using a basic concept of the present disclosure as defined in the following claims also fall within the scope of the present disclosure.

What is claimed is:

1. A two-electrode memory device, comprising:
a substrate;
a floating gate disposed on the substrate and configured to store electrons;
a tunneling insulating film disposed on the floating gate;
a channel disposed on the tunneling insulating film;
a source electrode and a drain electrode that are each disposed on the tunneling insulating film and that have electrical connection with the channel; and
a plurality of metal nanodots disposed in the tunneling insulating film and configured to provide electron tunneling between the floating gate and the channel through the tunneling insulating film.

2. The two-electrode memory device of claim 1, wherein the floating gate comprises a metal material and at least one of graphene, polysilicon, or silicon nitride (SiN).

3. The two-electrode memory device of claim 1, wherein the plurality of metal nanodots are made from a metal thin film that is deposited on the floating gate through an atomic layer deposition (ALD) process and annealed while depositing the tunneling insulating film on the metal thin film.

4. The two-electrode memory device of claim 1, wherein the plurality of metal nanodots comprise at least one of gold (Au), aluminum (Al), copper (Cu), silver (Ag), nickel (Ni), or germanium (Ge).

5. The two-electrode memory device of claim 1, wherein the two-electrode memory device is configured to perform a write operation or an erase operation based on (i) connecting one electrode of the source electrode or the drain electrode to a ground and (ii) applying a voltage to the other electrode of the source electrode or the drain electrode.

6. The two-electrode memory device of claim 5, wherein the floating gate is configured to:
store the electrons based on a negative voltage being applied to the other electrode, and
discharge the electrons based on a positive voltage being applied to the other electrode.

7. The two-electrode memory device of claim 1, wherein the substrate comprises at least one of polyimide or polydimethylsiloxane.

8. The two-electrode memory device of claim 1, wherein the tunneling insulating film comprises at least one of aluminum oxide (Al₂O₃), hexagonal boron nitride, silicon nitride (Si₃N₄), silicon oxide (SiO₂), or hafnium oxide (HfO₂).

9. The two-electrode memory device of claim 1, wherein the channel comprises at least one of zinc oxide (ZnO), molybdenum disulfide (MoS₂), molybdenum diselenide (MoSe₂), tungsten disulfide (WS₂), tungsten diselenide (WSe₂), silicon (Si), germanium (Ge), a semiconducting carbon nanotube, or black phosphorus.

10. The two-electrode memory device of claim 1, wherein the channel comprises a negative n-type semiconductor, and
wherein the channel is configured to:
decrease a resistance of the channel based on the floating gate having a positive potential; and
increase the resistance of the channel based on the floating gate having a negative potential.

11. The two-electrode memory device of claim 1, wherein the channel comprises a positive p-type semiconductor, and
wherein the channel is configured to:
increase a resistance of the channel based on the floating gate having a positive potential, and
decrease the resistance of the channel based on the floating gate having a negative potential.

12. The two-electrode memory device of claim 1, wherein each of the source electrode and the drain electrode comprises a stacked structure of chromium (Cr) and gold (Au).

13. A method for manufacturing a two-electrode memory device, the method comprising:
providing a substrate;
forming a floating gate on the substrate, the floating gate being configured to store electrons;
depositing a metal thin film on the floating gate;
depositing a seed layer on the metal thin film;
depositing a tunneling insulating film on the seed layer and performing an annealing process while depositing the tunneling insulating film to thereby form a plurality of metal nanodots with the metal thin film in the tunneling insulating film;
forming a channel on the tunneling insulating film; and
forming a source electrode and a drain electrode on the tunneling insulating film, wherein the source electrode and the drain electrode each have electrical connection with the channel, and
wherein the plurality of metal nanodots are configured to provide electron tunneling between the floating gate and the channel through the tunneling insulating film.

14. The method of claim 13, wherein the floating gate comprises a metal material and at least one of graphene, polysilicon, or silicon nitride (SiN).

15. The method of claim 13, wherein the plurality of metal nanodots comprise at least one of gold (Au), aluminum (Al), copper (Cu), silver (Ag), nickel (Ni), or germanium (Ge).

16. The method of claim 13, wherein the substrate comprises at least one of polyimide or polydimethylsiloxane.

17. The method of claim 13, wherein the tunneling insulating film comprises at least one of aluminum oxide (Al₂O₃), hexagonal boron nitride, silicon nitride (Si₃N₄), silicon oxide (SiO₂), or hafnium oxide (HfO₂).

18. The method of claim 13, wherein the channel comprises at least one of zinc oxide (ZnO), molybdenum disulfide (MoS₂), molybdenum diselenide (MoSe₂), tungsten disulfide (WS₂), tungsten diselenide (WSe₂), silicon (Si), germanium (Ge), a semiconducting carbon nanotube, or black phosphorus.

19. The method of claim 13, wherein each of the source electrode and the drain electrode comprises a stacked structure of chromium (Cr) and gold (Au).

20. The method of claim 13, wherein the seed layer comprises an aluminum layer.
